(19) United States
(12) Patent Application Publication
(10) Pub. No.: US 2005/0274996 A1
(43) Pub. Date: Dec. 15, 2005

(54) Solid-state imaging device and method for manufacturing the same

(75) Inventor: Naoki Iwawaki, Kyoto-shi (JP)

Correspondence Address: HAMRE, SCHUMANN, MUELLER & LARSON P.C., P.O. BOX 2902, MINNEAPOLIS, MN, 55402, US

(73) Assignee: Matsushita Electric Industrial Co., Ltd., Kadoma-shi (JP)

(21) Appl. No.: 11/150,457

(22) Filed: Jun. 10, 2005

(30) Foreign Application Priority Data
Jun. 14, 2004 (JP) 2004-175962

(51) Int. Cl. H01L 31/062

(52) U.S. Cl. 257/292

(57) ABSTRACT

A solid-state imaging device is provided, including: a semiconductor substrate; a photoelectric conversion portion formed in the semiconductor substrate; a gate insulation film formed on the semiconductor substrate so as to cover the photoelectric conversion portion; and a plurality of transfer gate electrodes that transfer charges generated at the photoelectric conversion portion in a vertical direction, the plurality of transfer gate electrodes being formed on the gate insulation film and being mutually insulated by silicon oxide films. The plurality of transfer gate electrodes include an impurity-doped amorphous silicon film or a poly-silicon film, and the gate insulation film has a multilayer configuration including a layer made of a material more resistant to oxidizing than silicon nitride, or has a single-layer configuration made of a material more resistant to oxidizing than silicon nitride.

### FIELD OF THE INVENTION

The present invention relates to a solid-state imaging device and a method for manufacturing the same.

### BACKGROUND OF THE INVENTION

Conventionally, various solid-state imaging devices have been proposed. For instance, JPH09(1997)-283733 A discloses a conventional solid-state imaging device. A conventional solid-state imaging device will be described below, with reference to drawings. FIG. 11 is a plan view for explaining the arrangement of transfer gate electrodes in a general solid-state imaging device. Note here that FIG. 11 is for showing the arrangement of first transfer gate electrodes 110 and second transfer gate electrodes 111 above a substrate 101, and therefore elements other than these are not illustrated. FIG. 12 is a cross-sectional view showing the configuration of the conventional solid-state imaging device, taken along the line A-A of FIG. 11. FIG. 13 is another cross-sectional view showing the configuration of the conventional solid-state imaging device, taken along the line B-B of FIG. 11.

As shown in FIG. 11, first transfer gate electrodes 110 and second transfer gate electrodes 111, formed above the substrate 101, partially overlap one another. As shown in FIG. 12 and FIG. 13, a first transfer gate electrode 110 and a second transfer gate electrode 111 are formed with a silicon oxide film 112 as an insulator intervening therebetween.

The following describes the conventional solid-state imaging device 100, with reference to FIG. 12. A n-type impurity diffusion region 103 is formed in a first p-type well region 102 formed on the n-type silicon substrate 101, and a p-type positive-charge storage region 104 is formed in the n-type impurity diffusion region 103 on the opposite side of the substrate 101. The p-type positive-charge storage region 104, the n-type impurity diffusion region 103 and the first p-type well region 102 form a photodiode that is made of a pn junction so as to constitute a light-receptive portion (photoelectric conversion portion) 105. This light-receptive portion 105 is formed corresponding to a pixel.

Further, a vertical register 106 is formed in the first p-type well region 102 on the n-type silicon substrate 101, and a second p-type well 107 also is formed in the vertical register 106 on the substrate 101 side. A p-type channel stopper region 108 is formed between: the n-type impurity diffusion region 103 and the p-type positive-charge storage region 104; and the vertical register 106 and the second p-type well 107. The vertical register 106, which is a region for transferring a charge in the vertical direction, is allowed to have a larger capacity by the second p-type well 107. Further, the p-type channel stopper region 108 electrically isolates the n-type impurity diffusion region 103 and the vertical register 106.

Moreover, a three-layered gate insulation film 109 is formed so as to cover the entire surface of the first p-type well region 102. The gate insulation film 109 covers the light-receptive portion 105, the vertical register 106 and the p-type channel stopper region 108 as well. Herein, the gate insulation film 109 is composed of three layers including: a silicon oxide film 115; a silicon nitride film 121; and a silicon oxide film 117.

On the gate insulation film 109, the first transfer gate electrodes 110 and the second transfer gate electrodes 111 are laminated, which are for transferring a charge generated at the light-receptive portion 105 in the vertical direction. The silicon oxide films 112 are formed between the first transfer gate electrodes 110 and the second transfer gate electrodes 111. Further, the first transfer gate electrodes 110 and the second transfer gate electrodes 111 are surrounded with the silicon oxide films 112.

The silicon oxide films 112, covering the first transfer gate electrodes 110 and the second transfer gate electrodes 111, are covered with a metal light-shielding film 113. The metal light-shielding film 113 prevents light from being incident directly on the vertical register 106. Further, the metal light-shielding film 113 and portions that are not covered with the metal light-shielding film 113 are covered with a boron-doped phosphosilicate glass (BPSG) film 114. Note here that the BPSG film 114 is a silicon oxide film containing boron and phosphorus. The BPSG film 114 is an interlayer insulation film between the metal light-shielding film 113 and an aluminum wiring (not illustrated) formed at an upper layer above the metal light-shielding film 113.

In the cross-sectional view taken along the line B-B of FIG. 11, the conventional solid-state imaging device 100 has the configuration shown in FIG. 13. As shown in FIG. 13, the gate insulation film 109 is formed so as to cover the first p-type well region 102 on the n-type silicon substrate 101, and the first transfer gate electrodes 110 and the second transfer gate electrodes 111 are formed alternately so as to contact with the gate insulation film 109. The second transfer gate electrodes 111 are formed over edge portions of the first transfer gate electrodes 110. Herein, the silicon oxide films 112 are formed between the first transfer gate electrodes 110 and the second transfer gate electrodes 111 so as to insulate them from one another. The silicon oxide films 112 are formed around the first transfer gate electrodes 110 and the second transfer gate electrodes 111 also, and the metal light-shielding film 113 and the BPSG film 114 are formed successively on the silicon oxide films 112.

A method for manufacturing such a conventional solid-state imaging device 100 will be described below, with reference to FIG. 14A to FIG. 14E. FIG. 14A to FIG. 14E are cross-sectional views showing the steps of the manufacturing method of a conventional solid-state imaging device. Note here that FIG. 14A to FIG. 14E show a portion similar to that shown in the cross-sectional view of FIG. 13. Firstly, as shown in FIG. 14A, a first p-type well region 102 is formed on a n-type silicon substrate 101, and a gate insulation film 109, composed of three layers including a silicon oxide film 115, a silicon nitride film 121 and a silicon oxide film 117, is formed over the entire surface of the first p-type well region 102 using a thermal oxidation apparatus, a low pressure chemical vapor deposition (CVD) apparatus or the like. Although not illustrated, before forming the gate insulation film 109, a necessary configuration such as a light-receptive portion is formed in the first p-type well region 102.

Next, as shown in FIG. 14B, a gate electrode material 118 including a n-type doped amorphous silicon film or a doped poly-silicon film with a thickness of about 0.5 μm is formed over the entire surface of the gate insulation film 109.

Next, photolithography and etching are applied to the gate electrode material 118 so as to remove unnecessary portions, whereby first transfer gate electrodes 110 as a gate region and a gate wiring region are formed. Thereafter, water is made from hydrogen and oxygen at low pressure and surfaces of the first transfer gate electrodes 110 are thermally oxidized using the water, whereby silicon oxide films 112 are formed on the first transfer gate electrodes 110 as shown in FIG. 14C.

Note here the silicon nitride film 121 generally is resistant to oxidizing. Therefore, an oxidation rate is faster in the first transfer gate electrodes 110 made of the doped amorphous silicon layer or the doped poly-silicon layer than in the silicon nitride film 121. For that reason, the silicon oxide films 112 are formed selectively over the first transfer gate electrodes 110. Note here that the silicon nitride film 121 also is oxidized during this step so as to be decreased in thickness, whereas the silicon oxide film 117 is increased in thickness.

Next, as shown in FIG. 14D, a gate electrode material 119 is formed to have a thickness of 0.5 μm on the silicon oxide films 112 and the gate insulation film 109. Since this step can be performed in a similar manner to the step of FIG. 14B, the detailed description therefor is omitted.

Next, photolithography and etching are applied to the gate electrode material 119 so as to remove unnecessary portions, whereby second transfer gate electrodes 111 as a gate region and a gate wiring region are formed. Thereafter, as shown in FIG. 14E, silicon oxide films 112 are formed on the second transfer gate electrodes 111. Since this step is similar to that described referring to FIG. 14C, the detailed description therefor is omitted.

Next, a metal light-shielding film 113 is formed on the silicon oxide films 112 formed on the first transfer gate electrodes 110 and the second transfer gate electrodes 111. Herein, the metal light-shielding film 113 is not formed at a light-receptive portion (not illustrated). Thereafter, a BPSG film 114 is formed over the entire surface using a low-pressure CVD apparatus, an atmospheric pressure CVD apparatus or the like. In this way, the conventional solid-state imaging device 100 shown in FIG. 13 can be manufactured.

In the case of manufacturing the solid-state imaging device 100 by the above-stated conventional manufacturing method, the following problems occur.

At the step of FIG. 14B, each of the silicon oxide film 115, the silicon nitride film 121 and the silicon oxide film 117, making up the gate insulation film 109, is formed to have a uniform thickness, so that the thickness of the gate insulation film 109 also becomes uniform. However, at the step of FIG. 14C, where the silicon oxide films 112 are formed on the first transfer gate electrodes 110 by thermal oxidation, the gate insulation film 109 also is oxidized. Since the silicon nitride film 121 is oxidized, the thickness of the gate insulation film 109 becomes nonuniform. More specifically, the gate insulation film 109 has the partially varied thickness as shown in FIG. 14C. As shown in FIG. 14C, at the portion of the gate insulation film 109 where the first transfer gate electrode 110 is formed, the film thicknesses of the silicon oxide film 115, the silicon nitride film 121 and the silicon oxide film 117 do not change from those prior to the thermal oxidation. However, at the exposed portion where the first transfer gate electrode 110 is not formed, although the film thickness of the silicon oxide film 115 does not change, the film thickness of the silicon nitride film 121 is decreased because of the oxidation and the film thickness of the silicon oxide film 117 is increased. Further, the film thickness of the gate insulation film 109 as a whole is increased. Following this, during the steps of FIG. 14D and FIG. 14E, the second transfer gate electrodes are formed at the portions of the gate insulation film 109 with the increased thickness.

FIG. 15 is a graph showing a potential (electric potential) in the charge transfer direction in the conventional solid-state imaging device. From FIG. 15, it can be understood that a potential in the range 131 under the first transfer gate electrode 110 is shallower than a potential in the range 132 under the second transfer gate electrode 111. That is to say, in the conventional solid-state imaging device 100, a potential barrier occurs in a transfer channel. Such a potential barrier causes a charge to be trapped during charge transferring, thus leading to an incomplete charge transfer, which means the problem of a low transfer efficiency.

### SUMMARY OF THE INVENTION

Therefore, with the foregoing in mind, it is an object of the present invention to provide a solid-state imaging device having a potential under a first transfer gate electrode identical to a potential under a second transfer gate electrode, thus allowing complete charge transfer to be performed, and to provide a manufacturing method for the same.

A first solid-state imaging device of the present invention includes: a semiconductor substrate; a photoelectric conversion portion formed in the semiconductor substrate; a gate insulation film formed on the semiconductor substrate so as to cover the photoelectric conversion portion; and a plurality of transfer gate electrodes that transfer charges generated at the photoelectric conversion portion in a vertical direction, the plurality of transfer gate electrodes being formed on the gate insulation film and being mutually insulated by silicon oxide films. The plurality of transfer gate electrodes include an impurity-doped amorphous silicon film or a poly-silicon film. The gate insulation film has a multilayer configuration including a layer made of a material more resistant to oxidizing than silicon nitride, or has a single-layer configuration made of a material more resistant to oxidizing than silicon nitride.

A second solid-state imaging device of the present invention includes: a semiconductor substrate; a photoelectric conversion portion formed in the semiconductor substrate; a gate insulation film formed on the semiconductor substrate so as to cover the photoelectric conversion portion; and a plurality of transfer gate electrodes that transfer charges generated at the photoelectric conversion portion in a vertical direction, the plurality of transfer gate electrodes being formed on the gate insulation film and being mutually insulated by silicon oxide films. The plurality of transfer gate electrodes include an impurity-doped amorphous silicon film or a poly-silicon film. In the gate insulation film, all positions contacting with the plurality of transfer gate electrodes have an equal film thickness in terms of a dielectric constant.

A first method for manufacturing a solid-state imaging device of the present invention includes the steps of forming a gate insulation film on a semiconductor substrate in which a photoelectric conversion portion is formed, the gate insulation film being formed so as to cover the photoelectric conversion portion and having a multilayer configuration including a layer made of a material more resistant to oxidizing than silicon nitride or a single-layer configuration made of a material more resistant to oxidizing than silicon nitride. A plurality of transfer gate electrodes are formed on the gate insulation film by repeating the following steps of: forming a transfer gate electrode including an impurity doped amorphous silicon film or a poly-silicon film on the gate insulation film, followed by thermal oxidation so as to form a silicon oxide film on a surface of the transfer gate electrode.

A second method for manufacturing a solid-state imaging device of the present invention includes the steps of: forming a gate insulation film on a semiconductor substrate in which a photoelectric conversion portion is formed, the gate insulation film being formed so as to cover the photoelectric conversion portion and including a multilayer film. A plurality of transfer gate electrodes are formed on the gate insulation film by repeating the following steps of: forming a transfer gate electrode including an impurity doped amorphous silicon film or a poly-silicon film on the gate insulation film, followed by thermal oxidation so as to form a silicon oxide film on a surface of the transfer gate electrode. The thermal oxidation allows all of positions of the gate insulation film contacting with the plurality of transfer gate electrodes to have an equal film thickness in terms of a dielectric constant.

### BRIEF DESCRIPTION OF THE DRAWINGS

FIG. 1 is a cross-sectional view showing a solid-state imaging device according to Embodiment 1 of the present invention.

FIG. 2 is another cross-sectional view showing the solid-state imaging device according to Embodiment 1 of the present invention.

FIG. 3A to FIG. 3E are cross-sectional views showing the steps of the manufacturing method of the solid-state imaging device according to Embodiment 1 of the present invention.

FIG. 4 is a cross-sectional view showing the configuration of a solid-state imaging device according to Embodiment 2 of the present invention.

FIG. 5 is another cross-sectional view showing the configuration of the solid-state imaging device according to Embodiment 2 of the present invention.

FIG. 6A to FIG. 6E are cross-sectional views showing the steps of the manufacturing method of the solid-state imaging device according to Embodiment 2 of the present invention.

FIG. 7 is a cross-sectional view showing the configuration of a solid-state imaging device according to Embodiment 3 of the present invention.

FIG. 8 is another cross-sectional view showing the configuration of the solid-state imaging device according to Embodiment 3 of the present invention.

FIG. 9A to FIG. 9E are cross-sectional views showing the steps of the manufacturing method of the solid-state imaging device according to Embodiment 3 of the present invention.

FIG. 10 is a cross-sectional view showing the configuration with three types of transfer gate electrodes.

FIG. 11 is a plan view for explaining the arrangement of transfer gate electrodes in a general solid-state imaging device.

FIG. 12 is a cross-sectional view showing the configuration of a conventional solid-state imaging device.

FIG. 13 is another cross-sectional view showing the configuration of the conventional solid-state imaging device.

FIG. 14A to FIG. 14E are cross-sectional views showing the steps of the manufacturing method of a conventional solid-state imaging device.

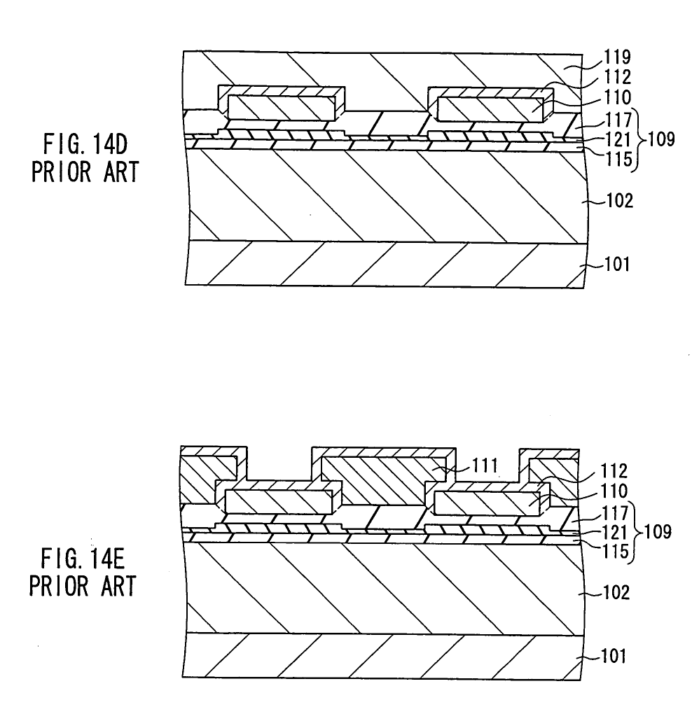

FIG. 15 is a graph showing a potential in the charge transfer direction in the conventional solid-state imaging device.

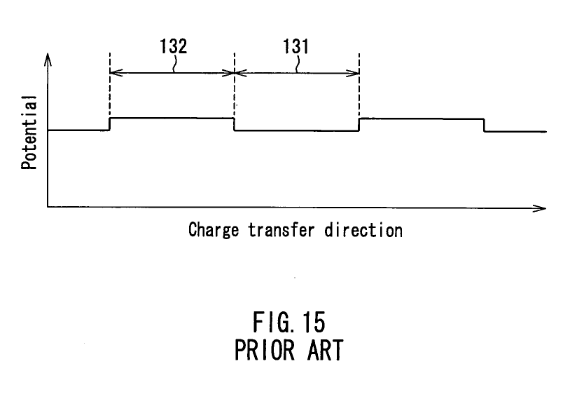

### DETAILED DESCRIPTION OF THE INVENTION

According to the first solid-state imaging device of the present invention, in the gate insulation film, all positions contacting with the plurality of transfer gate electrodes have an equal film thickness in terms of a dielectric constant. Therefore, potentials under the respective transfer gate electrodes are made equal to one another. Therefore, there is no potential barrier occurring in a transfer channel, which means a high transfer efficiency. Note here that positions in the gate insulation film being equal in film thickness in terms of a dielectric constant means that they are equal in capacity in the thickness direction of the gate insulation film. For instance, the film thicknesses in terms of a dielectric constant of a silicon oxide film used for the gate insulation film may be made equal to one another.

Preferably, in the first solid-state imaging device of the present invention, the silicon oxide films that insulate the plurality of transfer gate electrodes mutually are formed by making water from hydrogen and oxygen at low pressure and thermally oxidizing surfaces of the plurality of transfer gate electrodes using the water. Thereby, powerful thermal oxidation is enabled, so that the silicon oxide film becomes softened to have fluidity. Thus, the interface with the transfer gate electrodes can be made smooth and can be formed with a uniform thickness. For that reason, the silicon oxide film has high resistance to stress. Herein, at low pressure refers to a state from 13.3 Pa to 1.33×10⁴ Pa, for example.

Preferably, in the first solid-state imaging device of the present invention, the material more resistant to oxidizing than silicon nitride is aluminum oxide. With this configuration, the gate insulation film can have a uniform thickness. Therefore, there is no potential barrier occurring in a transfer channel, which means a high transfer efficiency.

Preferably, in the first solid-state imaging device of the present invention, the gate insulation film has a three-layered configuration including a silicon oxide film—an aluminum oxide film—a silicon oxide film. With this configuration, the gate insulation film can have a uniform thickness. Therefore, there is no potential barrier occurring in a transfer channel, which means a high transfer efficiency.

According to the second solid-state imaging device of the present invention, in the gate insulation film, all positions contacting with the plurality of transfer gate electrodes have an equal film thickness in terms of a dielectric constant. Thereby, potentials under the respective transfer gate electrodes are made equal to one another. Therefore, there is no potential barrier occurring in a transfer channel, which means a high transfer efficiency.

Preferably, in the second solid-state imaging device of the present invention, the silicon oxide films that insulate the plurality of transfer gate electrodes mutually are formed by making water from hydrogen and oxygen at low pressure and thermally oxidizing surfaces of the plurality of transfer gate electrodes using the water. Thereby, powerful thermal oxidation is enabled, so that the silicon-oxide film becomes softened to have fluidity. Thus, the interface with the transfer gate electrodes can be made smooth and can be formed with a uniform thickness. For that reason, the silicon oxide film has high resistance to stress.

Preferably, in the second solid-state imaging device of the present invention, the gate insulation film has a multilayer configuration with different ratios of thicknesses of the respective layers at different portions of the gate insulation film. With this configuration, when manufacturing the silicon oxide films on the surfaces of the transfer gate electrodes, all positions contacting with the plurality of transfer gate electrodes have an equal film thickness in terms of a dielectric constant even if the gate insulation film is oxidized. Therefore, there is no potential barrier occurring in a transfer channel, which means a high transfer efficiency.

Preferably, in the second solid-state imaging device of the present invention, the gate insulation film has a three-layered configuration including a silicon oxide film—a silicon nitride film—a silicon oxide film. With this configuration, in the gate insulation film, all positions contacting with the plurality of transfer gate electrodes have an equal film thickness in terms of a dielectric constant. Therefore, there is no potential barrier occurring in a transfer channel, which means a high transfer efficiency.

Preferably, in the second solid-state imaging device of the present invention, a configuration of the gate insulation film is varied depending on the transfer gate electrode contacting therewith. Thereby, in the gate insulation film, all positions contacting with the plurality of transfer gate electrodes can have an equal film thickness in terms of a dielectric constant. Therefore, there is no potential barrier occurring in a transfer channel, which means a high transfer efficiency.

Preferably, in the second solid-state imaging device of the present invention, the plurality of transfer gate electrodes include a first transfer gate electrode and a second transfer gate electrode. In the gate insulation film, a portion contacting with the first transfer gate electrode has a multilayer configuration at least including a silicon oxide film and a silicon nitride film. In the gate insulation film, a portion contacting with the second transfer gate electrode has a single layer configuration of a silicon oxide film. With this configuration, in the gate insulation film, all positions contacting with the plurality of transfer gate electrodes have an equal film thickness in terms of a dielectric constant. Therefore, there is no potential barrier occurring in a transfer channel, which means a high transfer efficiency.

Preferably, in the second solid-state imaging device of the present invention, in the gate insulation film, the portion contacting with the first transfer gate electrode has a three-layered configuration including a silicon oxide film—a silicon nitride film—a silicon oxide film. With this configuration, in the gate insulation film, all positions contacting with the plurality of transfer gate electrodes have an equal film thickness in terms of a dielectric constant. Therefore, there is no potential barrier occurring in a transfer channel, which means a high transfer efficiency.

According to the first manufacturing method for a solid-state imaging device of the present invention, the gate insulation film formed has a multilayer configuration including a layer made of a material more resistant to oxidizing than silicon nitride or a single-layer configuration made of a material more resistant to oxidizing than silicon nitride. Thereby, when the silicon oxide films are manufactured on the surfaces of the transfer gate electrodes, the gate insulation film is not oxidized and does not change in thickness. Thereby, potentials under the respective transfer gate electrodes are made equal to one another. Therefore, there is no potential barrier occurring in a transfer channel, which allows a solid-state imaging device with a high transfer efficiency to be manufactured.

Preferably, in the first manufacturing method for a solid-state imaging device according to the present invention, the material more resistant to oxidizing than silicon nitride is aluminum oxide. With this configuration, the gate insulation film can have a uniform thickness. Therefore, there is no potential barrier occurring in a transfer channel, which allows a solid-state imaging device with a high transfer efficiency to be manufactured. Preferably, in the first manufacturing method for a solid-state imaging device according to the present invention, the thermal oxidation is performed using water made from hydrogen and oxygen at low pressure. Thereby, powerful thermal oxidation is enabled, so that the silicon oxide film becomes softened to have fluidity. Thus, the interface with the transfer gate electrodes can be made smooth and can be formed with a uniform thickness. For that reason, a solid-state imaging device having the silicon oxide film with high resistance to stress can be manufactured.

According to the second manufacturing method for a solid-state imaging device of the present invention, in the step of forming the silicon oxide films on the surfaces of the transfer gate electrodes, all of positions of the gate insulation film contacting with the plurality of transfer gate electrodes are made to have an equal film thickness in terms of a dielectric constant. Thereby, potentials under the respective transfer gate electrodes are made equal to one another. Therefore, there is no potential barrier occurring in a transfer channel, which allows a solid-state imaging device with a high transfer efficiency to be manufactured.

Preferably, in the second manufacturing method for a solid-state imaging device according to the present invention, the gate insulation film has a three-layered configuration including a silicon oxide film—a silicon nitride film—a silicon oxide film. Thereby, there is no potential barrier occurring in a transfer channel, which allows a solid-state imaging device with a high transfer efficiency to be manufactured.

Preferably, in the second manufacturing method for a solid-state imaging device according to the present invention, in the step of forming the silicon oxide film on the surface of the transfer gate electrode, the thermal oxidation is performed until portions of the gate insulation film where the transfer gate electrode is not formed turn into a silicon oxide film having a single-layer configuration. Thereby, the thickness of the gate insulation film in terms of a dielectric constant at portions where the transfer gate electrodes are not formed can be controlled. Thus, there is no potential barrier occurring in a transfer channel, which allows a solid-state imaging device with a high transfer efficiency to be manufactured.

Preferably, the second manufacturing method for a solid-state imaging device according to the present invention, further includes the steps of: removing the silicon oxide film having a single-layer configuration; and forming at a position where the silicon oxide film having a single-layer configuration is removed a silicon oxide film having a same film thickness in terms of a dielectric constant as that at the portions of the gate insulation film contacting with the transfer gate electrode. In this way, the silicon oxide film is formed again, so that the thickness of the gate insulation film in terms of a dielectric constant at portions where the transfer gate electrodes are not formed can be controlled more accurately. Thus, there is no potential barrier occurring in a transfer channel, which allows a solid-state imaging device with a high transfer efficiency to be manufactured.

Preferably, in the second manufacturing method for a solid-state imaging device according to the present invention, the thermal oxidation is performed using water made from hydrogen and oxygen at low pressure. Thereby, powerful thermal oxidation is enabled, so that the silicon oxide film becomes softened to have fluidity. Thus, the interface with the transfer gate electrodes can be made smooth and can be formed with a uniform thickness. For that reason, a solid-state imaging device having the silicon oxide film with high resistance to stress can be manufactured.

### Embodiment 1

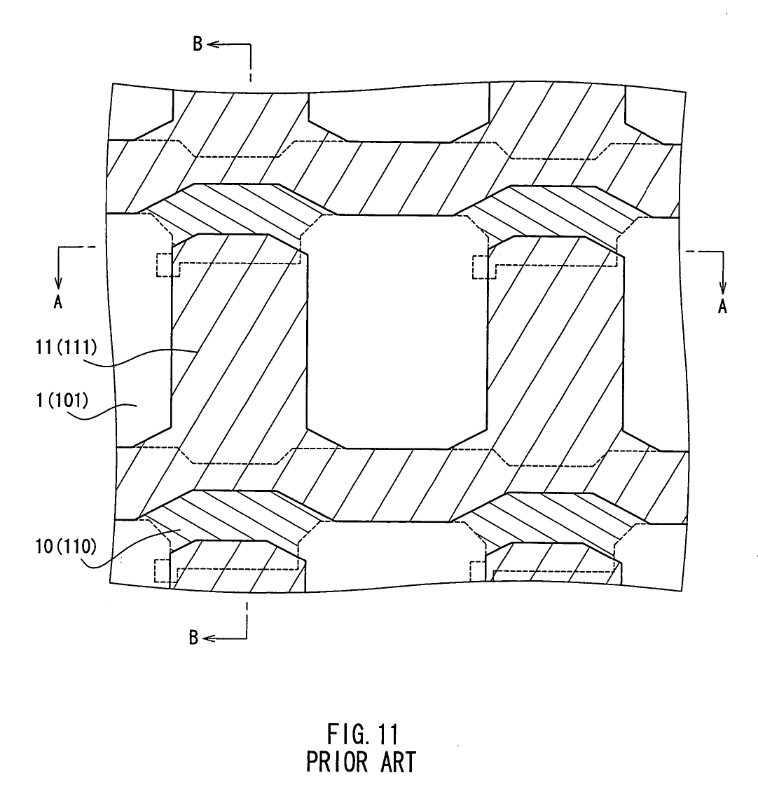

The following describes a solid-state imaging device and a manufacturing method for the same according to Embodiment 1 of the present invention, with reference to the drawings. Note here that the arrangement of transfer gate electrodes in the solid-state imaging device according to Embodiment 1 is similar to the arrangement of the transfer gate electrodes in the general solid-state imaging device shown in FIG. 11, and therefore FIG. 11 also is referred to in Embodiment 1. FIG. 11 is for showing the arrangement of first transfer gate electrodes 10 and second transfer gate electrodes 11 above a substrate 1, and therefore elements other than these are not illustrated.

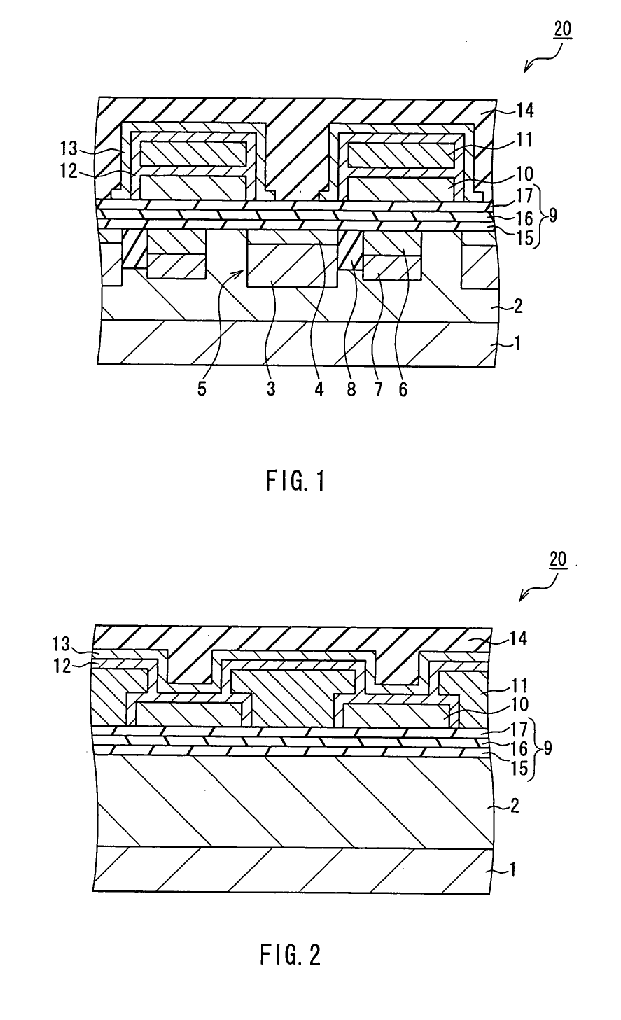

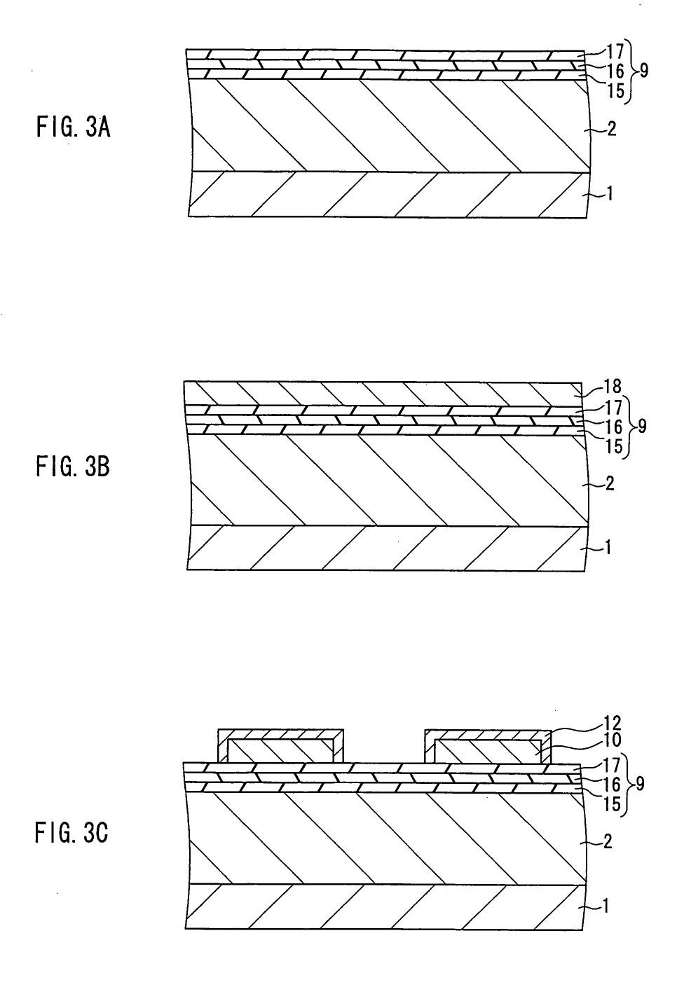

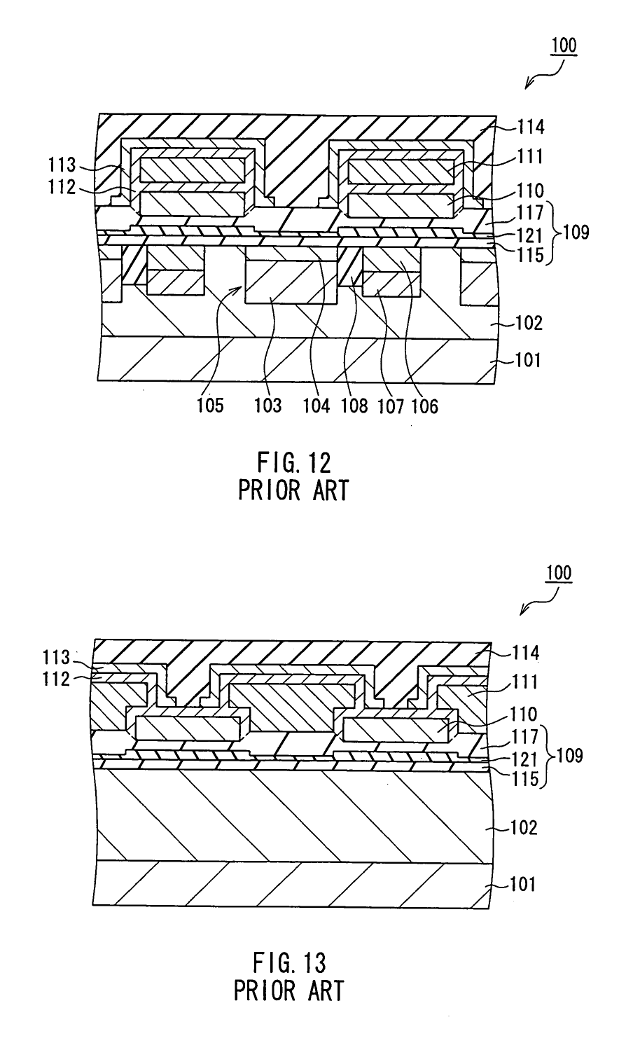

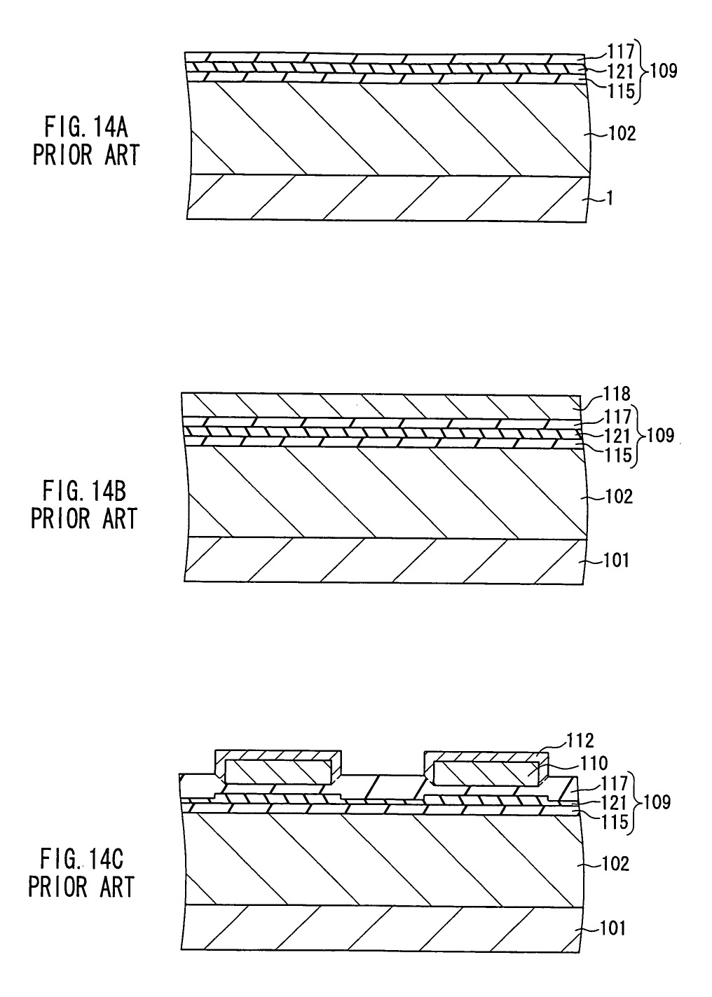

FIG. 1 is a cross-sectional view showing the solid-state imaging device according to Embodiment 1 of the present invention, taken along the line A-A of FIG. 11. FIG. 2 is another cross-sectional view showing the solid-state imaging device according to Embodiment 1 of the present invention, taken along the line B-B of FIG. 11. A gate insulation film 9 of the solid-state imaging device according to Embodiment 1 is composed of: a silicon oxide film (SiO₂) 15, an aluminum oxide film 16 and a silicon oxide film (SiO₂) 17. In the solid-state imaging device 20 of Embodiment 1, the configuration other than the gate insulation film 9 is substantially the same as the configuration of the conventional solid-state imaging device shown in FIG. 12 and FIG. 13.

As shown in FIG. 11, first transfer gate electrodes 10 and second transfer gate electrodes 11, formed above the substrate 1, partially overlap one another. As shown in FIG. 1 and FIG. 2, at these overlapping portions, the first transfer gate electrodes 10 and the second transfer gate electrodes 11 are formed with silicon oxide films 12 as an insulator intervening therebetween.

As shown in FIG. 1, a n-type impurity diffusion region 3 is formed in a first p-type well region 2 formed on the n-type silicon substrate 1, and a p-type positive-charge storage region 4 is formed in the n-type impurity diffusion region 3 on the opposite side of the substrate 1. The p-type positive-charge storage region 4, the n-type impurity diffusion region 3 and the first p-type well region 2 form a photodiode that is made of a pn junction so as to constitute a light-receptive portion (photoelectric conversion portion) 5. This light-receptive portion 5 is formed corresponding to a pixel.

Further, a vertical register 6 is formed in the first p-type well region 2 formed on the n-type silicon substrate 1, and a second p-type well 7 also is formed in the vertical register 6 on the substrate 1 side. Ap-type channel stopper region 8 is formed between: the n-type impurity diffusion region 3 and the p-type positive-charge storage region 4; and the vertical register 6 and the second p-type well 7. The vertical register 6, which is a region for transferring a charge in the vertical direction, is allowed to have a larger capacity by the second p-type well 7. Further, the p-type channel stopper region 8 electrically isolates the n-type impurity diffusion region 3 and the vertical register 6.

Moreover, the three-layered gate insulation film 9 is formed so as to cover the entire surface of the first p-type well region 2. The gate insulation film 9 covers the light-receptive portion 5, the vertical register 6 and the p-type channel stopper region 8 as well. Herein, the gate insulation film 9 is composed of three layers, including the silicon oxide film 15, the aluminum oxide film 16, and the silicon oxide film 17.

On the gate insulation film 9, the first transfer gate electrodes 10 and the second transfer gate electrodes 11 are laminated, which are for transferring a charge generated at the light-receptive portion 5 in the vertical direction. The silicon oxide films 12 are formed between the first transfer gate electrodes 10 and the second transfer gate electrodes 11. Further, the first transfer gate electrodes 10 and the second transfer gate electrodes 11 are surrounded with the silicon oxide films 12.

The silicon oxide films 12, surrounding the first transfer gate electrodes 10 and the second transfer gate electrodes 11, are covered with a metal light-shielding film 13. The metal light-shielding film 13 prevents light from being incident directly on the vertical register 6. Further, the metal light-shielding film 13 and portions that are not covered with the metal light-shielding film 13 are covered with a BPSG film 14. The BPSG film 14 is an interlayer insulation film between the metal light-shielding film 13 and an aluminum wiring (not illustrated) formed at an upper layer above the metal light-shielding film 13.

In the cross-sectional view taken along the line B-B of FIG. 11, the solid-state imaging device 20 of Embodiment 1 has the configuration shown in FIG. 2. As shown in FIG. 2, the gate insulation film 9 is formed so as to cover the first p-type well region 2 on the n-type silicon substrate 1, and the first transfer gate electrodes 10 and the second transfer gate electrodes 11 are formed alternately so as to contact with the gate insulation film 9. The second transfer gate electrodes 11 are formed over edge portions of the first transfer gate electrodes 10. Herein, the silicon oxide films 12 are formed between the first transfer gate electrodes 10 and the second transfer gate electrodes 11 so as to insulate them from one another. The silicon oxide films 12 are formed around the first transfer gate electrodes 10 and the second transfer gate electrodes 11 also, and the metal light-shielding film 13 and the BPSG film 14 are formed successively on the silicon oxide films 12.

In the solid-state imaging device 20 of Embodiment 1, as stated above, the gate insulation film 9 is composed of: the silicon oxide film 15; the aluminum oxide film 16 that is more resistant to oxidizing than silicon nitride; and the silicon oxide film 17. Therefore, the respective film thicknesses of the silicon oxide film 15, the aluminum oxide film 16 and the silicon oxide film 17 do not change significantly due to thermal oxidation during the manufacturing process described later, and can be kept uniform. Thus, the thickness of the gate insulation film 9 also can be kept uniform, so that a capacity in the thickness direction can be made constant. Thereby, a potential under the first transfer gate electrodes 10 and a potential under the second transfer gate electrodes 11 are equal to each other, which means no potential barrier occurring, and therefore charges can be transferred completely and a transfer efficiency is high.

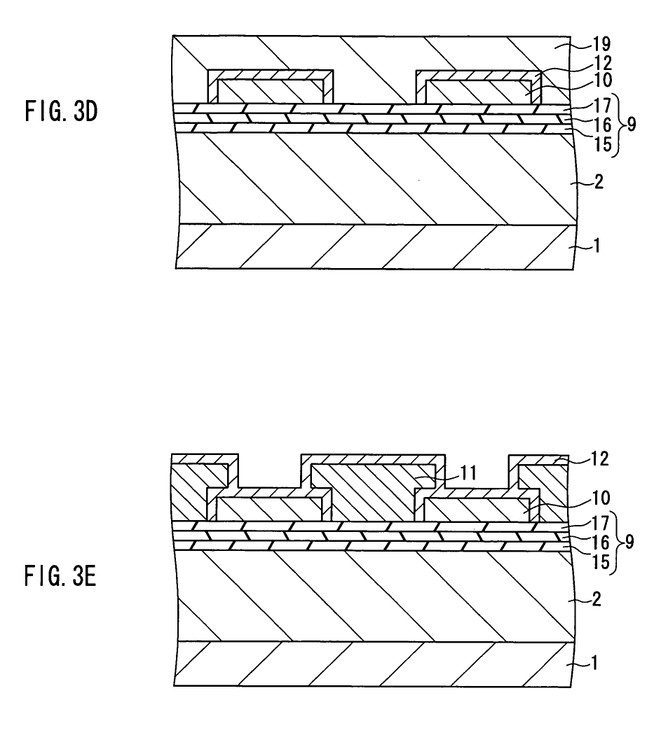

A method for manufacturing the solid-state imaging device 20 according to Embodiment 1 will be described below. FIG. 3A to FIG. 3E are cross-sectional views showing the steps of the manufacturing method of the solid-state imaging device according to Embodiment 1 of the present invention. Note here that FIG. 3A to FIG. 3E show a portion similar to that shown in the cross-sectional view of FIG. 2. Firstly, as shown in FIG. 3A, a first p-type well region 2 is formed on a n-type silicon substrate 1, and a gate insulation film 9, composed of three layers, including a silicon oxide film 15, an aluminum oxide film 16, and a silicon oxide film 17, is formed over the entire surface of the first p-type well region 2 using a thermal oxidation apparatus, a low pressure chemical vapor deposition (CVD) apparatus or the like. For instance, the thickness of the silicon oxide film 15 may be 20 nm, the thickness of the aluminum oxide film 16 may be 10 nm to 100 nm, and the thickness of the silicon oxide film 17 may be 5 nm. The aluminum oxide film 16 may be formed, for example, by electron resonance sputtering under the condition of 87.5 mT at a temperature of 100° C. and at a pressure of 9×10⁻⁶ Pa.

Although not illustrated, before forming the gate insulation film 9, a necessary configuration such as a light-receptive portion is formed in the first p-type well region 2.

Next, as shown in FIG. 3B, a gate electrode material 18 including a n-type doped amorphous silicon film or a doped poly-silicon film with a thickness of about 0.5 μm is formed over the entire surface of the gate insulation film 9.

Next, photolithography and etching are applied to the gate electrode material 18 so as to remove unnecessary portions, whereby first transfer gate electrodes 10 as a gate region and a gate wiring region are formed. Thereafter, water is made from hydrogen and oxygen at low pressure and thermal oxidation is performed using the water, whereby silicon oxide films 12 are formed on the first transfer gate electrodes 10 as shown in FIG. 3C. Herein, at low pressure refers to a state from 13.3 Pa to 1.33×10⁴ Pa, for example.

The thermal oxidation may be performed under the conditions of a pressure at 1.33×10² Pa and a processing temperature at 950° C., so as to form the silicon oxide film 12 of 50 nm to 150 nm in thickness. The thermal oxidation performed by making water from hydrogen and oxygen at low pressure and using the water is more powerful than general thermal oxidation. Therefore, thermal oxidation proceeds at a high speed, so that the silicon oxide film 12 becomes softened to have fluidity. Thus, mechanical strain occurring at the interface between the silicon oxide film 12 and the doped amorphous silicon or the doped poly-silicon can be alleviated to make the interface smooth. Further, the concentrated stress of the silicon oxide film 12 occurring at a corner portion of the first transfer gate electrodes 10 can be avoided by the viscous fluidity of the silicon oxide film 12, which can prevent the silicon oxide film 12 close to a corner portion of the first transfer gate electrode 10 from becoming too thin. Moreover, since the curvature radius of the first transfer gate electrode 10 at a corner portion increases, the resistance of the silicon oxide film 12 to stress becomes high.

Herein, since the aluminum oxide film 16 of the gate insulation film 9 is not oxidized even during this thermal oxidation, the film thickness thereof does not change, and therefore the thickness of the gate insulation film 9 can be kept uniform. Since the gate insulation film 9 has the uniform thickness, a capacity in the thickness direction of the gate insulation film 9 is constant at all positions of the film.

Next, as shown in FIG. 3D, a gate electrode material 19 is formed to have a thickness of 0.5 μm on the silicon oxide film 12 and the gate insulation film 9. Since this step can be performed in a similar manner to the step of FIG. 3B, the detailed description therefor is omitted.

Next, photolithography and etching are applied to the gate electrode material 19 so as to remove unnecessary portions, whereby second transfer gate electrodes 11 as a gate region and a gate wiring region are formed. Thereafter, as shown in FIG. 3E, silicon oxide films 12 are formed on the second transfer gate electrodes 11. Since this step is similar to that described referring to FIG. 3C, the detailed description therefor is omitted.

Next, a metal light-shielding film 13 is formed on the silicon oxide films 12 formed on the first transfer gate electrodes 10 and the second transfer gate electrodes 11. Herein, the metal light-shielding film 13 is not formed at a light-receptive portion (not illustrated). Thereafter, a BPSG film 14 is formed over the entire surface using a low-pressure CVD apparatus, an atmospheric pressure CVD apparatus or the like. Note here that the BPSG film 14 is a silicon oxide film containing boron and phosphorus. In this way, the solid-state imaging device 20 of Embodiment 1 shown in FIG. 2 can be manufactured.

In the thus manufactured solid-state imaging device 20 of Embodiment 1, a capacity of the gate insulation film 9 in the thickness direction is not varied from place to place but is constant at all positions of the film. Therefore, even when a plurality of transfer gate electrodes (the first transfer gate electrodes 10 and the second transfer gate electrodes 11) are formed on the gate insulation film 9, a potential barrier does not occur in a transfer channel, so that a transfer efficiency is high.

That is to say, considering the thickness of the gate insulation film 9 in terms of a dielectric constant of the silicon oxide film, the solid-state imaging device 20 has a uniform thickness at a portion contacting with the first transfer gate electrode 10 and at a portion contacting with the second transfer gate electrode 11. For that reason, the capacity in the thickness direction of the gate insulation film 9 has a uniform value at the portion contacting with the first transfer gate electrode 10 and at the portion contacting with the second transfer gate electrode 11. Therefore, a potential barrier does not occur in a transfer channel, thus enhancing a transfer efficiency.

Further, the silicon oxide films 12 formed between the first transfer gate electrodes 10 and the second transfer gate electrodes 11 are formed by thermal oxidation using water made from hydrogen and oxygen at low pressure, and therefore the silicon oxide films 12 have high resistance to stress.

Note here that as a material more resistant to oxidizing than silicon nitride that is one of the materials constituting the gate insulation film 9, the aluminum oxide film 16 is used in Embodiment 1, but other materials also may be used.

Further, although the gate insulation film 9 has a three-layered configuration, this may be a single layer made of a material that is more resistant to oxidizing than silicon nitride or be a multilayer including a layer made of a material that is more resistant to oxidizing than silicon nitride. For instance, the gate insulation film 9 may be a single layer of an aluminum oxide film only. In this case, the thickness of the aluminum oxide film (the gate insulation film 9) may be 10 nm to 100 nm. With this configuration also, the thickness of the gate insulation film 9 does not change due to thermal oxidation, and therefore a solid-state imaging device with a high transfer efficiency can be obtained.

### Embodiment 2

The following describes a solid-state imaging device according to Embodiment 2 of the present invention and a manufacturing method therefor, with reference to the drawings. Note here that the arrangement of transfer gate electrodes in the solid-state imaging device according to Embodiment 2 is similar to the arrangement of the transfer gate electrodes in the general solid-state imaging device shown in FIG. 11, and therefore FIG. 11 also is referred to in Embodiment 2. FIG. 11 is for showing the arrangement of first transfer gate electrodes 10 and second transfer gate electrodes 11 above a substrate 1, and therefore elements other than these are not illustrated.

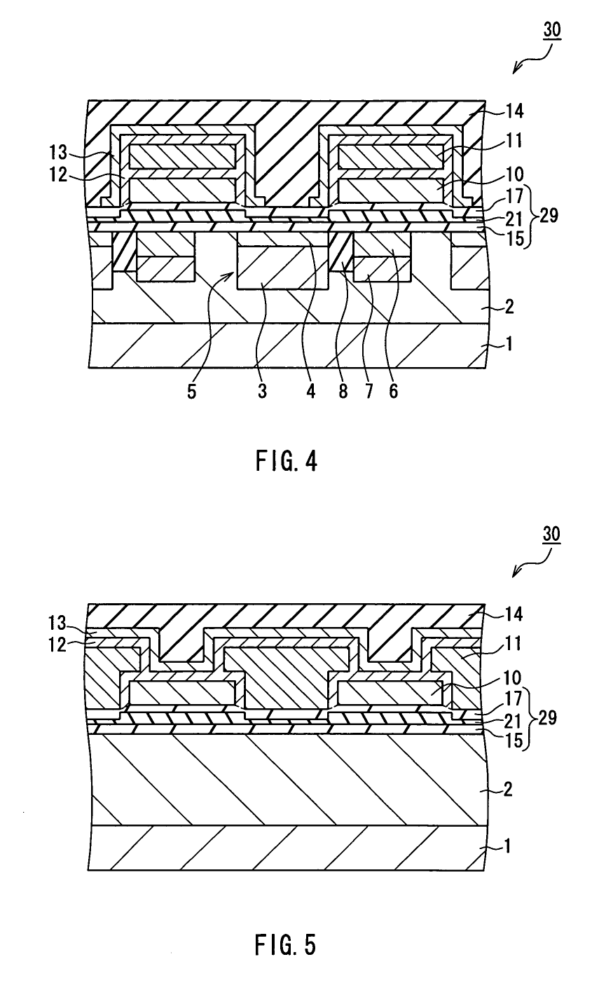

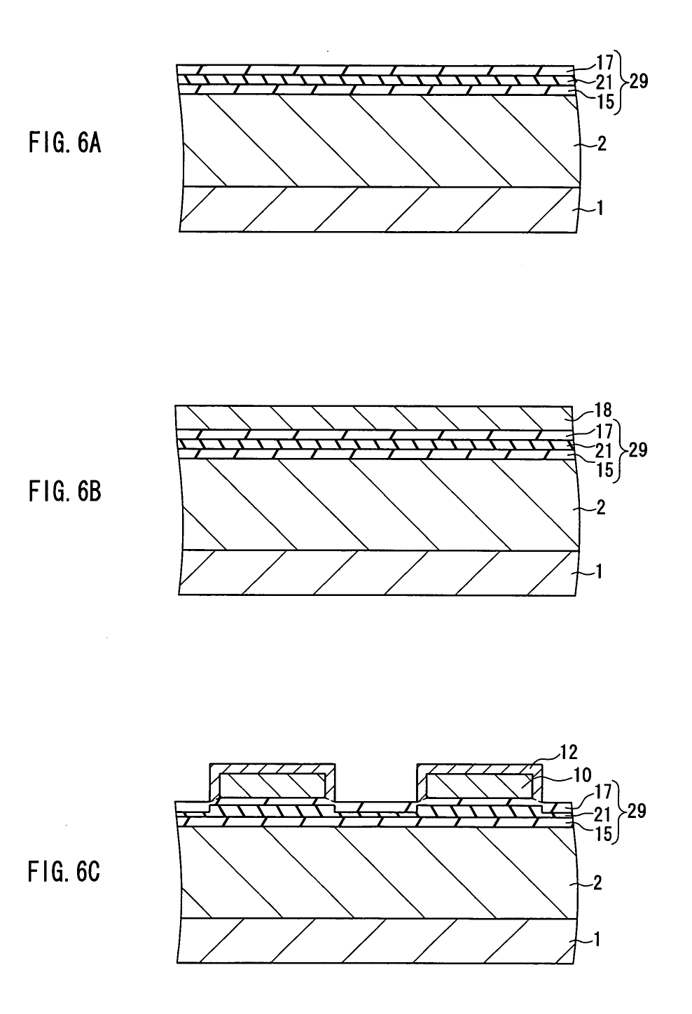

FIG. 4 is a cross-sectional view showing the configuration of the solid-state imaging device according to Embodiment 2 of the present invention, taken along the line A-A of FIG. 11. FIG. 5 is another cross-sectional view showing the configuration of the solid-state imaging device according to Embodiment 2 of the present invention, taken along the line B-B of FIG. 11.

The solid-state imaging device 30 according to Embodiment 2 has a configuration free from a potential barrier. A gate insulation film 29 of the solid-state imaging device 30 according to Embodiment 2 is composed of: a silicon oxide film 15, a silicon nitride film (Si₃N₄) 21 and a silicon oxide film 17. The thicknesses of the silicon nitride film 21 and the silicon oxide film 17 are not uniform but are varied partially. However, considering the thicknesses in terms of a dielectric constant of the silicon oxide film, the thickness of the gate insulation film 29 is uniform.

In the solid-state imaging device 30 of Embodiment 2, the configuration other than the gate insulation film 29 is substantially the same as the configuration of the solid-state imaging device 20 of Embodiment 1 shown in FIG. 1 and FIG. 2. Therefore, in FIG. 4 and FIG. 5, the same reference numerals are assigned to the elements having functions similar to those shown in FIG. 1 and FIG. 2, and their explanations are omitted.

In the solid-state imaging device 30 of Embodiment 2 shown in FIG. 4, a n-type silicon substrate 1, a first p-type well region 2, a n-type impurity diffusion region 3, a p-type positive-charge storage region 4, a light-receptive portion 5, a vertical register 6 and a second p-type well 7 have been described in Embodiment 1, and therefore their explanations are omitted. The three-layered gate insulation film 29, formed so as to cover the entire surface of the first p-type well region 2, covers the light-receptive portion 5, the vertical register 6 and the p-type channel stopper region 8. Herein, the gate insulation film 29 is composed of three layers including: the silicon oxide film 15; the silicon nitride film 21; and the silicon oxide film 17. The thicknesses of the silicon oxide film 17 and the silicon nitride film 21 are not uniform, and the thickness of the gate insulation film 29 also is not uniform.

On the gate insulation film 29, the first transfer gate electrodes 10 and the second transfer gate electrodes 11 are laminated, which are for transferring a charge generated at the light-receptive portion 5 in the vertical direction. The silicon oxide films 12 are formed between the first transfer gate electrodes 10 and the second transfer gate electrodes 11. Further, the first transfer gate electrodes 10 and the second transfer gate electrodes 11 are surrounded with the silicon oxide films 12.

The silicon oxide films 12, surrounding the first transfer gate electrodes 10 and the second transfer gate electrodes 11, are covered with a metal light-shielding film 13. Further, the metal light-shielding film 13 and portions that are not covered with the metal light-shielding film 13 are covered with a BPSG film 14.

In the cross-sectional view taken along the line B-B of FIG. 11, the solid-state imaging device 30 of Embodiment 2 has the configuration shown in FIG. 5. As shown in FIG. 5, the gate insulation film 29 is formed so as to cover the first p-type well region 2 on the n-type silicon substrate 1, and the first transfer gate electrodes 10 and the second transfer gate electrodes 11 are formed alternately so as to contact with the gate insulation film 29. The second transfer gate electrodes 11 are formed over edge portions of the first transfer gate electrodes 10. Herein, the silicon oxide films 12 are formed between the first transfer gate electrodes 10 and the second transfer gate electrodes 11 so as to insulate them from one another. The silicon oxide films 12 are formed around the first transfer gate electrodes 10 and the second transfer gate electrodes 11 also, and the metal light-shielding film 13 and the BPSG film 14 are formed successively on the silicon oxide films 12.

In the gate insulation film 29, the constituent ratios of the respective film thicknesses are different between the portion contacting with the first transfer gate electrode 10 and the portion contacting with the second transfer gate electrode 11. However, the film thicknesses in terms of a dielectric constant of the silicon oxide film are uniform at these portions. That is to say, in the gate insulation film 29, a capacity in the thickness direction is constant at the portion contacting with the first transfer gate electrode 10 and the portion contacting with the second transfer gate electrode 11. Thereby, a potential under the first transfer gate electrodes 10 and a potential under the second transfer gate electrodes 11 are equal to each other, which means no potential barrier occurring, and therefore charges can be transferred completely and a transfer efficiency is high.

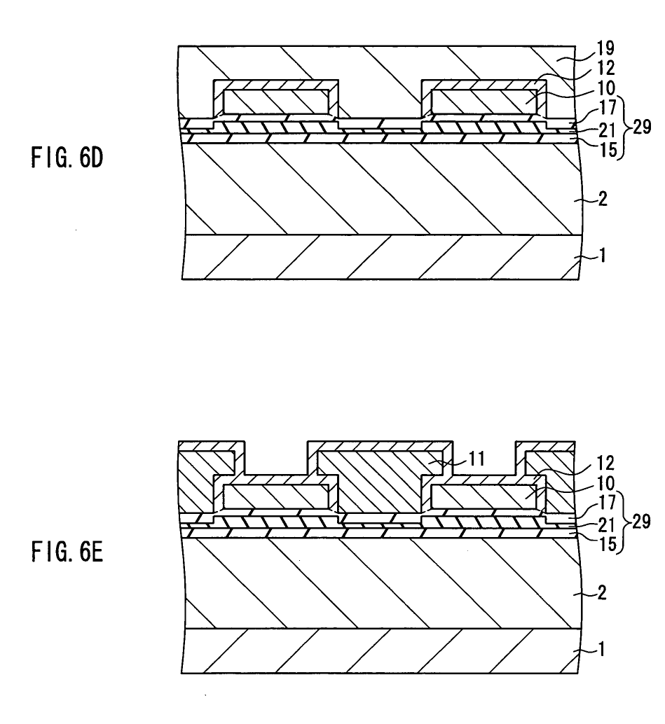

A method for manufacturing the solid-state imaging device 30 according to Embodiment 2 will be described below. FIG. 6A to FIG. 6E are cross-sectional views showing the steps of the manufacturing method of the solid-state imaging device according to Embodiment 2 of the present invention. Note here that FIG. 6A to FIG. 6E show a portion similar to that shown in the cross-sectional view of FIG. 5. Firstly, as shown in FIG. 6A, a first p-type well region 2 is formed on a n-type silicon substrate 1, and a gate insulation film 29, composed of three layers including a silicon oxide film 15, a silicon nitride film 21 and a silicon oxide film 17, is formed over the entire surface of the first p-type well region 2 using a thermal oxidation apparatus, a low pressure chemical vapor deposition (CVD) apparatus or the like. For instance, the thickness of the silicon oxide film 15 may be 20 nm, the thickness of the silicon nitride film 21 may be 40 nm, and the thickness of the silicon oxide film 17 may be 5 nm. Note here that in this case the thickness of the gate insulation film 29 in terms of a dielectric constant of the silicon oxide film is 45 nm.

Although not illustrated, before forming the gate insulation film 29, a necessary configuration such as a light-receptive portion is formed in the first p-type well region 2.

Next, as shown in FIG. 6B, a gate electrode material 18 including a n-type doped amorphous silicon film or a doped poly-silicon film with a thickness of about 0.5 μm is formed over the entire surface of the gate insulation film 29.

Next, photolithography and etching are applied to the gate electrode material 18 so as to remove unnecessary portions, whereby first transfer gate electrodes 10 as a gate region and a gate wiring region are formed. Thereafter, water is made from hydrogen and oxygen at low pressure and thermal oxidation is performed using the water, whereby silicon oxide films 12 are formed on the first transfer gate electrodes 10 as shown in FIG. 6C.

The thermal oxidation may be performed under the conditions of a pressure at 1.33×10² Pa and a processing temperature at 950° C., so as to form the silicon oxide film 12 of 50 nm to 150 nm in thickness. As a result of this thermal oxidation, the silicon nitride film 21 of the gate insulation film 29 at a portion where the first transfer gate electrode 10 is not formed turns into a silicon oxide film. After the thermal oxidation under these conditions, the thickness of the gate insulation film 29 at a portion where the first transfer gate electrode 10 is not formed is as follows: the thickness of the silicon oxide film 15 is 20 nm, the thickness of the silicon nitride film 21 is 30 nm and the thickness of the silicon oxide film 17 is 10 nm. Note here that the thickness of the gate insulation film 29 changes by the thermal oxidation, but the thickness of the gate insulation film 29 in terms of a dielectric constant of the silicon oxide film is kept at 45 nm, similar to that prior to the thermal oxidation. Further, the thickness of the gate insulation film 29 at a portion where the first transfer gate electrode 10 is formed does not change during the thermal oxidation, and therefore the thickness at the portion in terms of a dielectric constant of a silicon oxide film is kept at 45 nm, similar to that prior to the thermal oxidation.

Next, as shown in FIG. 6D, a gate electrode material 19 is formed to have a thickness of 0.5 μm on the silicon oxide film 12 and the gate insulation film 29. Since this step can be performed in a similar manner to the step of FIG. 6B, the detailed description therefor is omitted.

Next, photolithography and etching are applied to the gate electrode material 19 so as to remove unnecessary portions, whereby second transfer gate electrodes 11 as a gate region and a gate wiring region are formed. Thereafter, as shown in FIG. 6E, silicon oxide films 12 are formed on the second transfer gate electrodes 11. Since this step is similar to that described referring to FIG. 6C, the detailed description therefor is omitted.

Next, a metal light-shielding film 13 is formed on the silicon oxide films 12 formed on the first transfer gate electrodes 10 and the second transfer gate electrodes 11. Herein, the metal light-shielding film 13 is not formed at a light-receptive portion (not illustrated). Thereafter, a BPSG film 14 is formed over the entire surface using a low-pressure CVD apparatus, an atmospheric pressure CVD apparatus or the like. In this way, the solid-state imaging device 30 of Embodiment 2 shown in FIG. 5 can be manufactured.

In the thus manufactured solid-state imaging device 30 of Embodiment 2, a capacity of the gate insulation film 29 in the thickness direction is not varied from place to place but is constant at all positions of the film. Therefore, even when a plurality of transfer gate electrodes (the first transfer gate electrodes 10 and the second transfer gate electrodes 11) are formed on the gate insulation film 29, a potential barrier does not occur in a transfer channel, so that a transfer efficiency is high.

That is to say, considering the thickness of the gate insulation film 29 in terms of a dielectric constant of the silicon oxide film, the solid-state imaging device 30 has a uniform thickness at a portion contacting with the first transfer gate electrode 10 and at a portion contacting with the second transfer gate electrode 11. For that reason, a capacity in the thickness direction of the gate insulation film 29 has a uniform value at the portion contacting with the first transfer gate electrode 10 and at the portion contacting with the second transfer gate electrode 11. Therefore, a potential barrier does not occur in a transfer channel, thus enhancing a transfer efficiency.

Further, the silicon oxide films 12 formed between the first transfer gate electrodes 10 and the second transfer gate electrodes 11 are formed by thermal oxidation using water made from hydrogen and oxygen at low pressure, and therefore the silicon oxide films 12 have high resistance to stress.

Note here that the configuration of the gate insulation film 29 is not limited to the configuration shown in Embodiment 2.

### Embodiment 3

The following describes a solid-state imaging device according to Embodiment 3 of the present invention and a manufacturing method therefor, with reference to the drawings. Note here that the arrangement of transfer gate electrodes in the solid-state imaging device according to Embodiment 3 is similar to the arrangement of the transfer gate electrodes in the general solid-state imaging device shown in FIG. 11, and therefore FIG. 11 also is referred to in Embodiment 3. FIG. 11 is for showing the arrangement of first transfer gate electrodes 10 and second transfer gate electrodes 11 above a substrate 1, and therefore elements other than these are not illustrated.

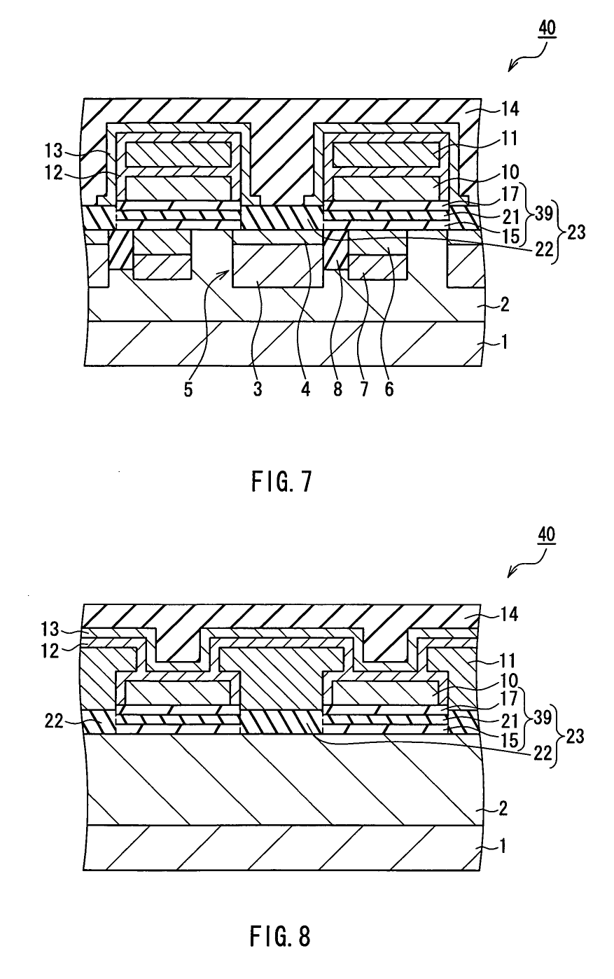

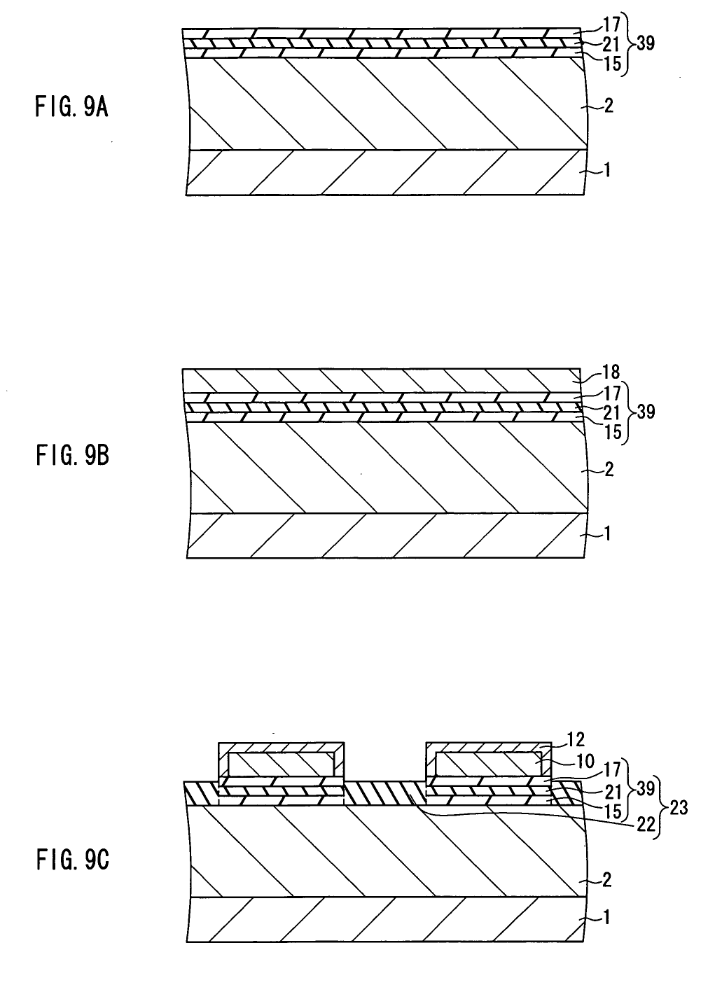

FIG. 7 is a cross-sectional view showing the configuration of the solid-state imaging device according to Embodiment 3 of the present invention, taken along the line A-A of FIG. 11. FIG. 8 is another cross-sectional view showing the configuration of the solid-state imaging device according to Embodiment 3 of the present invention, taken along the line B-B of FIG. 11.

The solid-state imaging device 40 according to Embodiment 3 includes a gate insulation film 23 formed on a first p-type well region 2 so as to cover a light-receptive portion 5, a vertical register 6 and a p-type channel stopper region 8. The gate insulation film 23 includes: a first gate insulation film 39 having a three-layered configuration composed of a silicon oxide film 15, a silicon nitride film 21 and a silicon oxide film 17; and a second gate insulation film 22 that is a single layer of a silicon oxide film. In the gate insulation film 23, the first gate insulation film 39 is formed at a position contacting with a first transfer gate electrode 10 and the second gate insulation film 22 is formed at a position contacting with a second transfer gate electrode 11.

In the solid-state imaging device 40 of Embodiment 3, the configuration other than the gate insulation film 23 is substantially the same as the configuration of the solid-state imaging device 20 of Embodiment 1 shown in FIG. 1 and FIG. 2. Therefore, in FIG. 7 and FIG. 8, the same reference numerals are assigned to the elements having functions similar to those shown in FIG. 1 and FIG. 2, and their explanations are omitted.

In the solid-state imaging device 40 of Embodiment 3 shown in FIG. 7, a n-type silicon substrate 1, a first p-type well region 2, a n-type impurity diffusion region 3, a p-type positive-charge storage region 4, a light-receptive portion 5, a vertical register 6 and a second p-type well 7 have been described in Embodiment 1, and therefore their explanations are omitted. The gate insulation film 23, including the first gate insulation film 39 and the second gate insulation film 22, is formed so as to cover the entire surface of the first p-type well region 2. The first gate insulation film 39 is composed of the laminate of the silicon oxide film 15, the silicon nitride film 21 and the silicon oxide film 17. The second gate insulation film- 22 is composed of the single layer of the silicon oxide film.

On the gate insulation film 23, the first transfer gate electrodes 10 and the second transfer gate electrodes 11 are laminated. The silicon oxide films 12 are formed between the first transfer gate electrodes 10 and the second transfer gate electrodes 11. Further, the first transfer gate electrodes 10 and the second transfer gate electrodes 11 are surrounded with the silicon oxide films 12.

The silicon oxide films 12, surrounding the first transfer gate electrodes 10 and the second transfer gate electrodes 11, are covered with a metal light-shielding film 13. Further, the metal light-shielding film 13 and portions that are not covered with the metal light-shielding film 13 are covered with a BPSG film 14.

In the cross-sectional view taken along the line B-B of FIG. 11, the solid-state imaging device 40 of Embodiment 3 has the configuration shown in FIG. 8. As shown in FIG. 8, the gate insulation film 23 is formed so as to cover the first p-type well region 2 on the n-type silicon substrate 1, and the first transfer gate electrodes 10 and the second transfer gate electrodes 11 are formed alternately so as to contact with the gate insulation film 23. More specifically, the first transfer gate electrode 10 is formed so as to contact with the first gate insulation film 39 and the second transfer fate electrode 11 is formed so as to contact with the second gate insulation film 22. The second transfer gate electrodes 11 are formed over edge portions of the first transfer gate electrodes 10. Herein, the silicon oxide films 12 are formed between the first transfer gate electrodes 10 and the second transfer gate electrodes 11 so as to insulate them from one another. The silicon oxide films 12 are formed around the first transfer gate electrodes 10 and the second transfer gate electrodes 11 also, and the metal light-shielding film 13 and the BPSG film 14 are formed successively on the silicon oxide films 12.

The thickness of the first gate insulation film 39 in terms of a dielectric constant of the silicon oxide film is the same as the thickness of the second gate insulation film 22 in terms of a dielectric constant of the silicon oxide film. That is to say, a capacity in the thickness direction is constant at the first gate insulation film 39 and at the second gate insulation film 22. Thereby, a potential under the first transfer gate electrodes 10 and a potential under the second transfer gate electrodes 11 are equal to each other, which means no potential barrier occurring, and therefore charges can be transferred completely and a transfer efficiency is high.

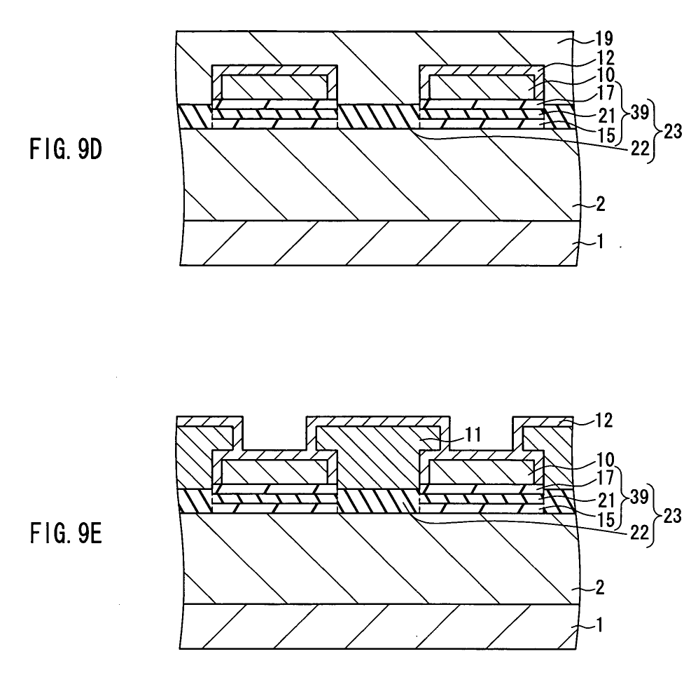

A method for manufacturing the solid-state imaging device 40 according to Embodiment 3 will be described below. FIG. 9A to FIG. 9E are cross-sectional views showing the steps of the manufacturing method of the solid-state imaging device according to Embodiment 3 of the present invention. Note here that FIG. 9A to FIG. 9E show a portion similar to that shown in the cross-sectional view of FIG. 8. Firstly, as shown in FIG. 9A, a first p-type well region 2 is formed on a n-type silicon substrate 1, and a first gate insulation film 39, composed of three layers including a silicon oxide film 15, a silicon nitride film 21 and a silicon oxide film 17, is formed over the entire surface of the first p-type well region 2 using a thermal oxidation apparatus, a low pressure CVD apparatus or the like. For instance, the thickness of the silicon oxide film 15 may be 20 nm, the thickness of the silicon nitride film 21 may be 40 nm, and the thickness of the silicon oxide film 17 may be 5 nm. Note here that in this case the thickness of the first gate insulation film 39 in terms of a dielectric constant of the silicon oxide film is 45 nm.

Although not illustrated, before forming the first gate insulation film 39, a necessary configuration such as a light-receptive portion is formed in the first p-type well region 2.

Next, as shown in FIG. 9B, a gate electrode material 18 including a n-type doped amorphous silicon film or a doped poly-silicon film with a thickness of about 0.5 μm is formed over the entire surface of the gate insulation film 39.

Next, photolithography and etching are applied to the gate electrode material 18 so as to remove unnecessary portions, whereby first transfer gate electrodes 10 as a gate region and a gate wiring region are formed. Thereafter, water is made from hydrogen and oxygen at low pressure and thermal oxidation is performed using the water, whereby silicon oxide films 12 are formed on the first transfer gate electrodes 10 as shown in FIG. 9C.

The thermal oxidation may be performed under the conditions of a pressure at 1.33×10² Pa and a processing temperature at 950° C., so as to form the silicon oxide film 12 of 50 nm to 150 nm in thickness. As a result of this thermal oxidation, at a portion of the silicon nitride film 21 of the first gate insulation film 39 where the first transfer gate electrode 10 is not formed turns into a silicon oxide film. As a result of the thermal oxidation, the silicon nitride film 21 at that portion is entirely oxidized, which portion is converted to a second gate insulation film 22 that is a single layer of a silicon oxide film. That is, as a result of this thermal oxidation, at a portion of the first gate insulation film 39 where the first transfer gate electrode 10 is not formed, the second gate insulation film 22, composed of the single layer of the silicon oxide film, can be formed to have thickness of 45 nm. Thereby, the gate insulation film 23 can be formed, including the first gate insulation film 39 having the three-layered configuration and the second gate insulation film 22 as the single layer.

Alternatively, the silicon oxide film that is formed by the thermal oxidation at a portion of the first gate insulation film 39 where the first transfer gate electrode 10 is not formed may be removed by etching, for example, using buffered hydrogen fluoride, and a second gate insulation film 22 made of silicon oxide may be formed again at that portion by a CVD technique or the like. With such a process, the thickness of the second gate insulation film 22 can be controlled, so as to enhance the thickness accuracy of the second gate insulation film 22. Thereby, a second gate insulation film 22 with a desired thickness can be manufactured with reliability.

Next, as shown in FIG. 9D, a gate electrode material 19 is formed to have a thickness of 0.5 μm on the silicon oxide film 12 and the gate insulation film 23. Since this step can be performed in a similar manner to the step of FIG. 9B, the detailed description therefor is omitted.

Next, photolithography and etching are applied to the gate electrode material 19 so as to remove unnecessary portions, whereby second transfer gate electrodes 11 as a gate region and a gate wiring region are formed. Thereafter, as shown in FIG. 9E, silicon oxide films 12 are formed on the second transfer gate electrodes 11. Since this step is similar to that described referring to FIG. 9C, the detailed description therefor is omitted.

Next, a metal light-shielding film 13 is formed on the silicon oxide films 12 formed on the first transfer gate electrodes 10 and the second transfer gate electrodes 11. Herein, the metal light-shielding film 13 is not formed at a light-receptive portion (not illustrated). Thereafter, a BPSG film 14 is formed over the entire surface using a low-pressure CVD apparatus, an atmospheric pressure CVD apparatus or the like. In this way, the solid-state imaging device 40 of Embodiment 3 shown in FIG. 8 can be manufactured.

In the thus manufactured solid-state imaging device 40 of Embodiment 3, a capacity of the gate insulation film 23 in the thickness direction is not varied from place to place but is constant at all positions of the film. Therefore, even when a plurality of transfer gate electrodes (the first transfer gate electrodes 10 and the second transfer gate electrodes 11) are formed on the gate insulation film 23, a potential barrier does not occur in a transfer channel, so that a transfer efficiency is high.

That is to say, in the solid-state imaging device 40, the thickness of the first gate insulation film 39, contacting with the first transfer gate electrode 10, in terms of a dielectric constant of the silicon oxide film is the same as the thickness of the second gate insulation film 22, contacting with the second transfer gate electrode 11, in terms of a dielectric constant of the silicon oxide film. That is to say, a capacity in the thickness direction has a uniform value at the first gate insulation film 39 and at the second gate insulation film 22, and therefore potential barrier does not occur in a transfer channel, thus enhancing a transfer efficiency.

Further, the silicon oxide films 12 formed between the first transfer gate electrodes 10 and the second transfer gate electrodes 11 are formed by thermal oxidation using water made from hydrogen and oxygen at low pressure, and therefore the silicon oxide films 12 have high resistance to stress.

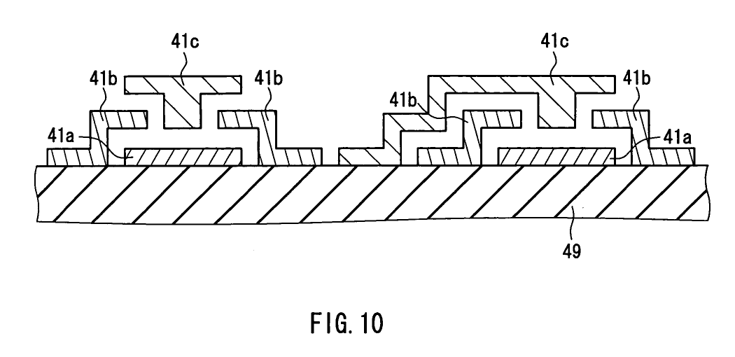

It should be noted that materials and configurations specifically shown in Embodiments 1 to 3 are only illustrative examples, and the present invention should not be construed as limited to only these specific examples. For instance, although Embodiments 1 to 3 show the configuration having two types of transfer gate electrodes, the number of the types of the transfer gate electrode is not limited to two. For instance, the configuration may include three types of transfer gate electrodes. FIG. 10 is a cross-sectional view showing the configuration with three types of transfer gate electrodes. Note here that FIG. 10 is for showing the arrangement of transfer gate electrodes 41a, 41b and 41c and a gate insulation film 49, and therefore other members such as silicon oxide film are omitted.

For instance, the solid-state imaging device on which three types of transfer gate electrodes 41a, 41b and 41c are formed on the gate insulation film 49 as shown in FIG. 10 also can be configured to have a configuration similar to the above-stated Embodiments 1 to 3 and can be manufactured by similar methods. Thereby, in the gate insulation film 49, a capacity in the thickness direction can be made equal at the respective portions contacting with the transfer gate electrodes 41a, 41b and 41c. Therefore, potentials under the respective transfer gate electrodes 41a, 41b and 41c can be made equal, whereby a potential barrier does not occur in a transfer channel, thus enhancing a transfer efficiency.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

1. A solid-state imaging device, comprising:
a semiconductor substrate;
a photoelectric conversion portion formed in the semiconductor substrate;
a gate insulation film formed on the semiconductor substrate so as to cover the photoelectric conversion portion; and
a plurality of transfer gate electrodes that transfer charges generated at the photoelectric conversion portion in a vertical direction, the plurality of transfer gate electrodes being formed on the gate insulation film and being mutually insulated by silicon oxide films,
wherein the plurality of transfer gate electrodes comprise an impurity-doped amorphous silicon film or a poly-silicon film, and
the gate insulation film has a multilayer configuration including a layer made of a material more resistant to oxidizing than silicon nitride, or has a single-layer configuration made of a material more resistant to oxidizing than silicon nitride.

2. The solid-state imaging device according to claim 1, wherein the silicon oxide films that insulate the plurality of transfer gate electrodes mutually are formed by making water from hydrogen and oxygen at low pressure and thermally oxidizing surfaces of the plurality of transfer gate electrodes using the water.

3. The solid-state imaging device according to claim 1 wherein the material more resistant to oxidizing than silicon nitride is aluminum oxide.

4. The solid-state imaging device according to claim 1, wherein the gate insulation film has a three-layered configuration comprising a silicon oxide film—an aluminum oxide film—a silicon oxide film.

5. A solid-state imaging device, comprising:
a semiconductor substrate;
a photoelectric conversion portion formed in the semiconductor substrate;
a gate insulation film formed on the semiconductor substrate so as to cover the photoelectric conversion portion; and
a plurality of transfer gate electrodes that transfer charges generated at the photoelectric conversion portion in a vertical direction, the plurality of transfer gate electrodes being formed on the gate insulation film and being mutually insulated by silicon oxide films,
wherein the plurality of transfer gate electrodes comprise an impurity-doped amorphous silicon film or a poly-silicon film, and
in the gate insulation film, all positions contacting with the plurality of transfer gate electrodes have an equal film thickness in terms of a dielectric constant.

6. The solid-state imaging device according to claim 5, wherein the silicon oxide films that insulate the plurality of transfer gate electrodes mutually are formed by making water from hydrogen and oxygen at low pressure and thermally oxidizing surfaces of the plurality of transfer gate electrodes using the water.

7. The solid-state imaging device according to claim 5, wherein the gate insulation film has a multilayer configuration with different ratios of thicknesses of the respective layers at different portions of the gate insulation film.

8. The solid-state imaging device according to claim 7, wherein the gate insulation film has a three-layered configuration comprising a silicon oxide film—a silicon nitride film—a silicon oxide film.

9. The solid-state imaging device according to claim 5, wherein a configuration of the gate insulation film is varied depending on the transfer gate electrode contacting therewith.

10. The solid-state imaging device according to claim 9,
wherein the plurality of transfer gate electrodes comprise a first transfer gate electrode and a second transfer gate electrode,
in the gate insulation film, a portion contacting with the first transfer gate electrode has a multilayer configuration at least comprising a silicon oxide film and a silicon nitride film, and
in the gate insulation film, a portion contacting with the second transfer gate electrode has a single layer configuration of a silicon oxide film.

11. The solid-state imaging device according to claim 10, wherein in the gate insulation film, the portion contacting with the first transfer gate electrode has a three-layered configuration comprising a silicon oxide film—a silicon nitride film—a silicon oxide film.

12. A method for manufacturing a solid-state imaging device, comprising the steps of:
forming a gate insulation film on a semiconductor substrate in which a photoelectric conversion portion is formed, the gate insulation film being formed so as to cover the photoelectric conversion portion and having a multilayer configuration comprising a layer made of a material more resistant to oxidizing than silicon nitride or a single-layer configuration made of a material more resistant to oxidizing than silicon nitride; and
forming a plurality of transfer gate electrodes on the gate insulation film by repeating the following steps of forming a transfer gate electrode comprising an impurity doped amorphous silicon film or a poly-silicon film on the gate insulation film, followed by thermal oxidation so as to form a silicon oxide film on a surface of the transfer gate electrode.

13. The method for manufacturing a solid-state imaging device according to claim 12, wherein the material more resistant to oxidizing than silicon nitride is aluminum oxide.

14. The method for manufacturing a solid-state imaging device according to claim 12, wherein the thermal oxidation is performed using water made from hydrogen and oxygen at low pressure.

15. A method for manufacturing a solid-state imaging device, comprising the steps of:
forming a gate insulation film on a semiconductor substrate in which a photoelectric conversion portion is formed, the gate insulation film being formed so as to cover the photoelectric conversion portion and comprising a multilayer film; and
forming a plurality of transfer gate electrodes on the gate insulation film by repeating the following steps of: forming a transfer gate electrode comprising an impurity doped amorphous silicon film or a poly-silicon film on the gate insulation film, followed by thermal oxidation so as to form a silicon oxide film on a surface of the transfer gate electrode,
wherein the thermal oxidation allows all of positions of the gate insulation film contacting with the plurality of transfer gate electrodes to have an equal film thickness in terms of a dielectric constant.

16. The method for manufacturing a solid-state imaging device according to claim 15, wherein the gate insulation film has a three-layered configuration comprising a silicon oxide film—a silicon nitride film—a silicon oxide film.

17. The method for manufacturing a solid-state imaging device according to claim 15, wherein in the step of forming the silicon oxide film on the surface of the transfer gate electrode, the thermal oxidation is performed until portions of the gate insulation film where the transfer gate electrode is not formed turn into a silicon oxide film having a single-layer configuration.

18. The method for manufacturing a solid-state imaging device according to claim 17, further comprising the steps of:
removing the silicon oxide film having a single-layer configuration; and
forming at a position where the silicon oxide film having a single-layer configuration is removed a silicon oxide film having a same film thickness in terms of a dielectric constant as that at the portions of the gate insulation film contacting with the transfer gate electrode.

19. The method for manufacturing a solid-state imaging device according to claim 15, wherein the thermal oxidation is performed using water made from hydrogen and oxygen at low pressure.
